(19) United States
(12) Patent Application Publication
(10) Pub. No.: US 2025/0109014 A1
(43) Pub. Date: Apr. 3, 2025

(54) Method For Manufacturing Vibration Device

(71) Applicant: SEIKO EPSON CORPORATION, Tokyo (JP)

(72) Inventor: Yusuke MATSUZAWA, Chino (JP)

(21) Appl. No.: 18/897,401

(22) Filed: Sep. 26, 2024

(30) Foreign Application Priority Data
Sep. 28, 2023 (JP) 2023-167251

(51) Int. Cl. B81C 1/00

(52) U.S. Cl. CPC B81C 1/0015; B81C 2201/0121

(57) ABSTRACT

A method for manufacturing a vibration device includes: preparing a base including a semiconductor substrate having a first surface, on which a circuit element is formed, and a second surface, and a first insulating layer disposed on the first surface of the semiconductor substrate and covering the circuit element; forming a second insulating layer by depositing an insulator on a fifth surface of the first insulating layer on a side opposite to the semiconductor substrate; planarizing at least a part of a third surface of the second insulating layer on a side opposite to the base by polishing; forming a mount electrode on the polished third surface of the second insulating layer; and bonding a vibration element to the mount electrode.

The present application is based on, and claims priority from JP Application Serial Number 2023-167251, filed Sep. 28, 2023, the disclosure of which is hereby incorporated by reference herein in its entirety.

### BACKGROUND

### 1. Technical Field

The present disclosure relates to a method for manufacturing a vibration device.

### 2. Related Art

JP-A-2021-057755 discloses a method for manufacturing a vibration device in which a vibration element is bonded to a base substrate on which an integrated circuit is formed. An insulating layer including a plurality of wiring layers is formed on an upper surface of the base substrate, and the vibration element electrically coupled to the wiring layer is formed on the insulating layer.

However, in the configuration of JP-A-2021-057755, a surface of the insulating layer including the plurality of wiring layers has poor planarity, and thus, when the vibration element is mounted on the surface of the insulating layer, the vibration element and the wiring layer are not stably bonded, which is problematic.

### SUMMARY

According to an aspect of the present disclosure, a method for manufacturing a vibration device includes: preparing a base including a semiconductor substrate having a first surface, on which a circuit element is formed, and a second surface, and a first insulating layer disposed on the first surface of the semiconductor substrate and covering the circuit element; forming a second insulating layer by depositing an insulator on a surface of the first insulating layer on a side opposite to the semiconductor substrate; planarizing at least a part of a surface of the second insulating layer on a side opposite to the base by polishing; forming a mount electrode on the polished surface of the second insulating layer; and bonding a vibration element to the mount electrode.

### BRIEF DESCRIPTION OF THE DRAWINGS

FIG. 1 is a perspective view illustrating a configuration of a vibration device.

FIG. 2 is a plan view illustrating the configuration of the vibration device.

FIG. 3 is a sectional view of the vibration device illustrated in FIG. 2 taken along line III-III.

FIG. 4A is a sectional view illustrating a method for manufacturing the vibration device.

FIG. 4B is a sectional view illustrating the method for manufacturing the vibration device.

FIG. 4C is a sectional view illustrating the method for manufacturing the vibration device.

FIG. 4D is a sectional view illustrating the method for manufacturing the vibration device.

FIG. 4E is a sectional view illustrating the method for manufacturing the vibration device.

FIG. 4F is a sectional view illustrating the method for manufacturing the vibration device.

FIG. 4G is a sectional view illustrating the method for manufacturing the vibration device.

FIG. 4H is a sectional view illustrating the method for manufacturing the vibration device.

FIG. 4I is a sectional view illustrating the method for manufacturing the vibration device.

FIG. 4J is a sectional view illustrating the method for manufacturing the vibration device.

FIG. 4K is a sectional view illustrating the method for manufacturing the vibration device.

FIG. 5A is a sectional view illustrating a method for manufacturing a vibration device according to a modification.

FIG. 5B is a sectional view illustrating the method for manufacturing the vibration device according to the modification.

FIG. 5C is a sectional view illustrating the method for manufacturing the vibration device according to the modification.

FIG. 5D is a sectional view illustrating the method for manufacturing the vibration device according to the modification.

FIG. 5E is a sectional view illustrating the method for manufacturing the vibration device according to the modification.

FIG. 5F is a sectional view illustrating the method for manufacturing the vibration device according to the modification.

FIG. 5G is a sectional view illustrating the method for manufacturing the vibration device according to the modification.

FIG. 5H is a sectional view illustrating the method for manufacturing the vibration device according to the modification.

FIG. 5I is a sectional view illustrating the method for manufacturing the vibration device according to the modification.

FIG. 5J is a sectional view illustrating the method for manufacturing the vibration device according to the modification.

FIG. 5K is a sectional view illustrating the method for manufacturing the vibration device according to the modification.

### DESCRIPTION OF EMBODIMENTS

In the following drawings, three mutually orthogonal axes are referred to as an X axis, a Y axis, and a Z axis, respectively. A direction along the X axis is referred to as an “X direction”, a direction along the Y axis is referred to as a “Y direction”, a direction along the Z axis is referred to as a “Z direction”, a direction indicated by an arrow is a + direction, and a direction opposite to the +direction is a − direction. A +Z direction may also be referred to as “upward”, “upper side”, or “front side”, a −Z direction may also be referred to as “downward”, “lower side”, or “back side”, and viewing from the +Z direction or the −Z direction may also be referred to as plan view or in plane. A surface on a + side in the Z direction is described as an “upper surface” or “front surface”, and a surface on a − side opposite to the + side in the Z direction is described as a “lower surface” or “back surface”.

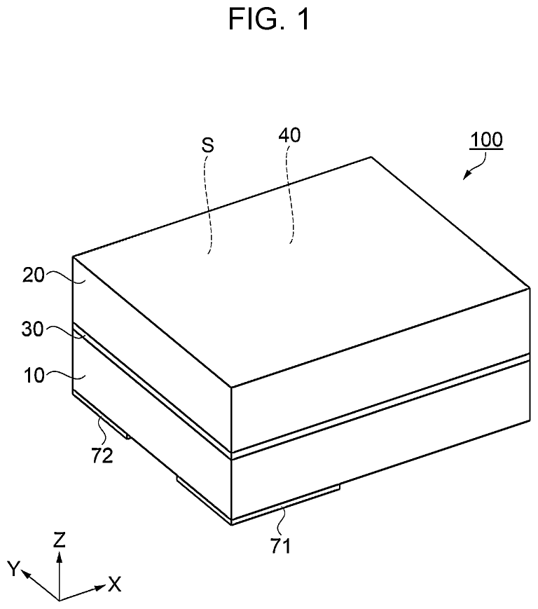

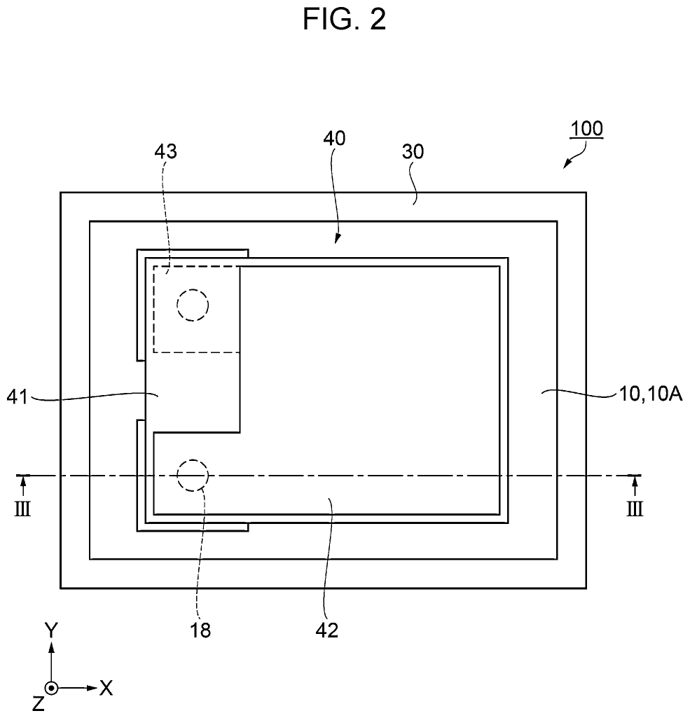

First, a configuration of a vibration device 100 will be described with reference to FIGS. 1 to 3. FIG. 2 illustrates the vibration device 100 with a lid 20 removed for the sake of convenience in describing an internal configuration.

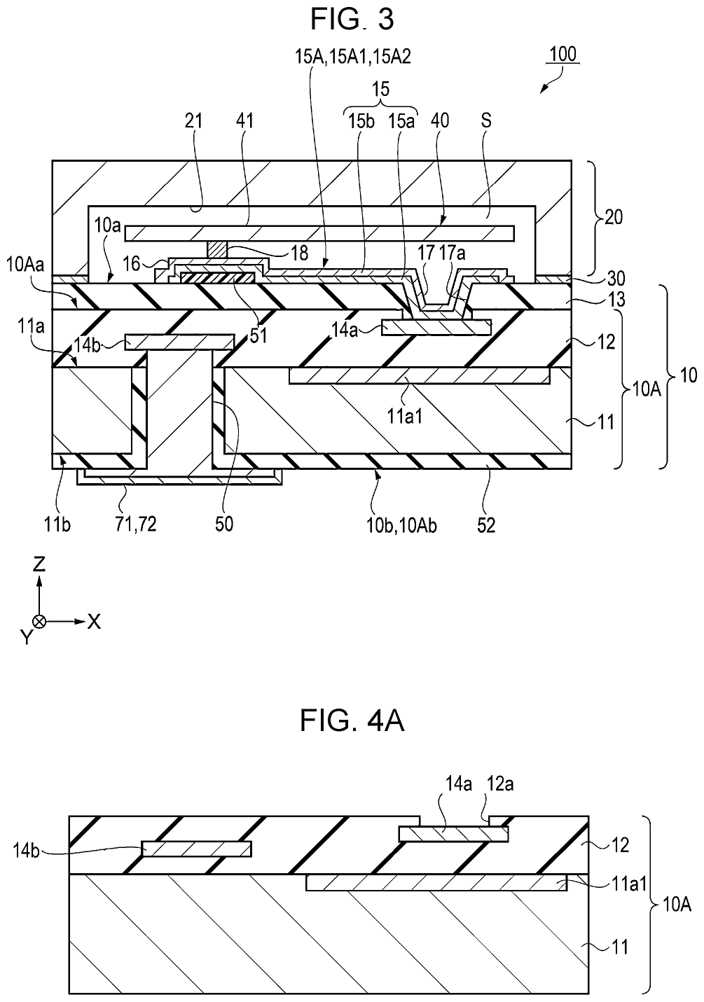

As illustrated in FIGS. 1 and 2, the vibration device 100 includes a base 10, the lid 20 disposed on the base 10, a bonding layer 30 bonding the base 10 and the lid 20 to each other, and a vibration element 40 (see FIG. 3) mounted on the base 10.

As illustrated in FIG. 2, the bonding layer 30 is formed in a frame shape in a region surrounding the vibration element 40, in other words, in a region where the base 10 and the lid 20 are bonded to each other. The bonding layer 30 is bonded by surface activated bonding using, for example, gold (Au). The bonding is not limited to using gold (Au), and copper (Cu), aluminum (Al), or the like may also be used.

As illustrated in FIG. 3, the base 10 includes a base 10A and a second insulating layer 13. The base 10A includes a semiconductor substrate 11 and a first insulating layer 12.

The semiconductor substrate 11 has a first surface 11a and a second surface 11b which is a surface opposite to the first surface 11a. The base 10 has a third surface 10a and a fourth surface 10b which is a surface opposite to the third surface 10a. The base 10A has a fifth surface 10Aa and a fourth surface 10Ab which is a surface opposite to the fifth surface 10Aa.

The semiconductor substrate 11 is, for example, a silicon substrate. A circuit element 11a1 including a transistor or the like is formed on the first surface 11a of the semiconductor substrate 11.

The circuit element 11a1 is, for example, a circuit in which a plurality of active elements such as transistors (not illustrated) are electrically coupled by wiring. The circuit element 11a1 oscillates, for example, the vibration element 40. The circuit element 11a1 may also be a temperature compensation circuit that corrects a vibration characteristic of the vibration element 40 according to a temperature change.

The first insulating layer 12 is disposed on the first surface 11a of the semiconductor substrate 11 so as to cover the circuit element 11a1. A plurality of wiring layers (not illustrated) are provided in the first insulating layer 12. Further, a pad electrode 14a covered with the first insulating layer 12 and electrically coupled to the circuit element 11a1 is provided in the base 10.

The second insulating layer 13 made of an oxide is formed on the base 10A, that is, on the fifth surface 10Aa of the base 10A. The third surface 10a of the second insulating layer 13 on a side opposite to the base 10A is planarized by polishing.

The first insulating layer 12 and the second insulating layer 13 may be made of, for example, SiO₂ (silicon oxide). A material of the first insulating layer 12 and the second insulating layer 13 is not limited to SiO₂ (silicon oxide) and may be SiN (silicon nitride) or the like.

A metal pattern 15A is formed on the second insulating layer 13. The metal pattern 15A includes a mount electrode 16, a contact electrode 17 provided in an opening 17a that is formed in a region of the first insulating layer 12 and the second insulating layer 13 which overlaps the pad electrode 14a in plan view, and wiring 15 that couples the mount electrode 16 and the contact electrode 17 to each other.

The wiring 15 is, for example, a laminated film of a TiW (tungsten titanium) film 15a and a Au (gold) film 15b.

A Ti (titanium) film may be used instead of the TiW film 15a.

The mount electrode 16 is electrically coupled to the circuit element 11al via the wiring 15, the contact electrode 17, and the pad electrode 14a. The circuit element 11a1 is electrically coupled to any one of external coupling terminals 71 and 72 disposed on the fourth surface 10b of the base 10 via a through electrode 50.

Specifically, the external coupling terminals 71 and 72 include a power supply external terminal, a ground external terminal, and an oscillation output external terminal electrically coupled to the circuit element 11a1. With such a configuration, the circuit element 11a1 is driven by power supplied from the outside via the power supply external terminal, oscillates the vibration element 40 to generate an oscillation signal, and outputs the oscillation signal to the outside via the oscillation output external terminal.

The vibration element 40 includes an element substrate 41, a first excitation electrode 42 (see FIG. 2) disposed on one surface of the element substrate 41, and a second excitation electrode 43 (see FIG. 2) disposed on the other surface of the element substrate 41.

The first excitation electrode 42 and the second excitation electrode 43 may be made of, for example, a metal material such as gold (Au), silver (Ag), platinum (Pt), palladium (Pd), iridium (Ir), copper (Cu), aluminum (Al), nickel (Ni), chromium (Cr), titanium (Ti), or tungsten (W), or alloys thereof.

When forming the vibration element 40, the base 10, in other words, the third surface 10a of the second insulating layer 13, is planarized before the mount electrode 16 is formed, so that the mount electrode 16 and the circuit element 11a1 can be electrically coupled in a stable state. As a result, the circuit element 11a1 and the vibration element 40 can be electrically coupled in a stable state.

The mount electrode 16 is provided on the third surface 10a of the base 10. The mount electrode 16 is electrically coupled to the vibration element 40 via a metal bump 18. The vibration element 40 is fixed to the third surface 10a of the base 10 by being bonded with the metal bump 18. The metal bump 18 may be a microbump or a stud bump.

The lid 20 is implemented by, for example, a silicon substrate and is a box-shaped container having a recess 21 for forming a cavity S as a housing space. The base 10 and the lid 20 are bonded to each other with the bonding layer 30 interposed in between, so that the vibration element 40 is housed in the recess 21 of the lid 20. That is, the vibration element 40 is disposed in a hermetically sealed space surrounded by the base 10 and the lid 20. The hermetically sealed space is referred to as the cavity S.

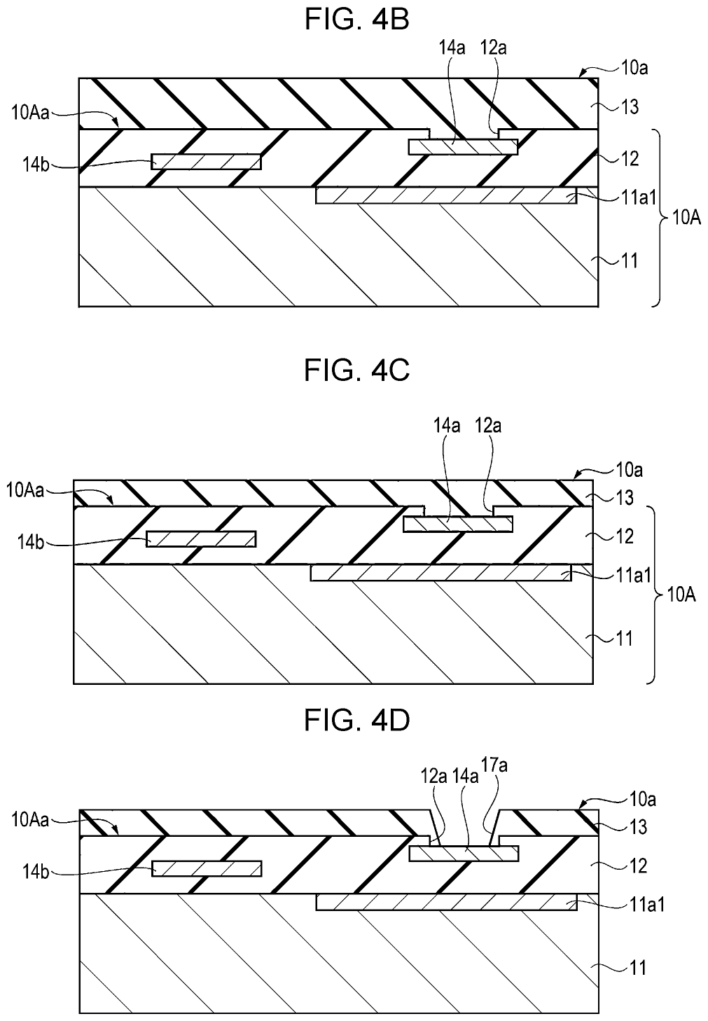

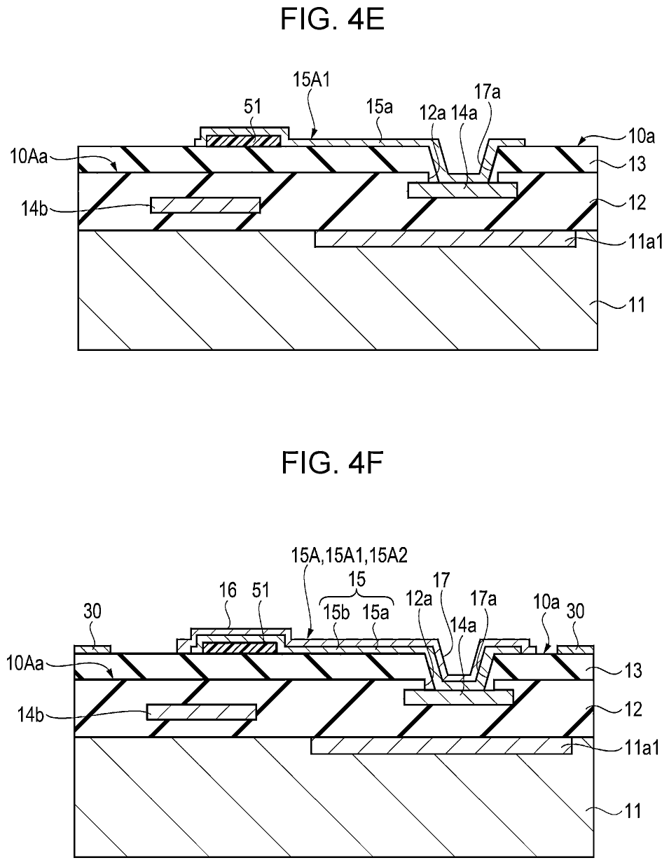

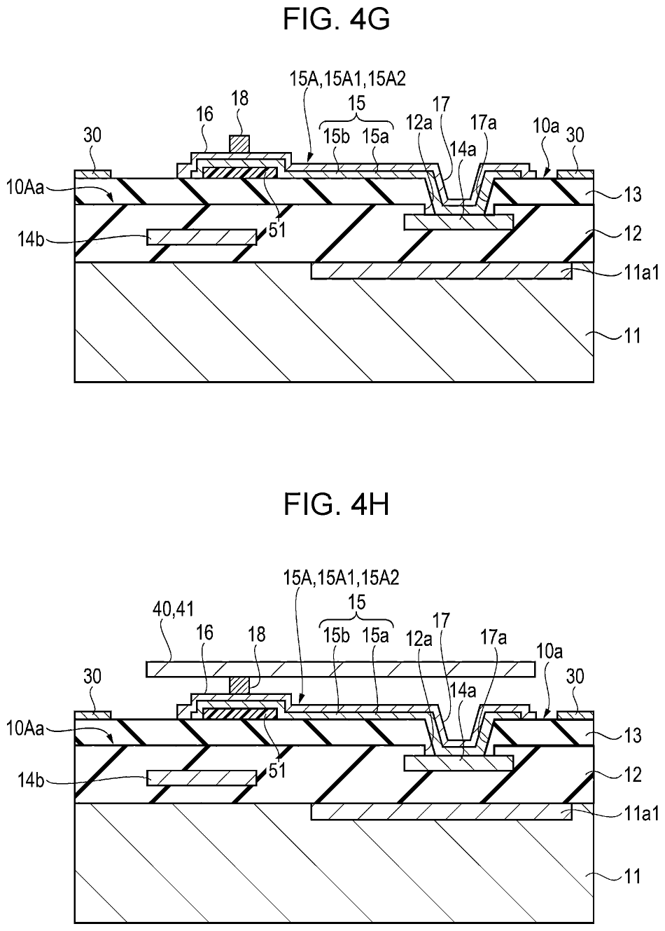

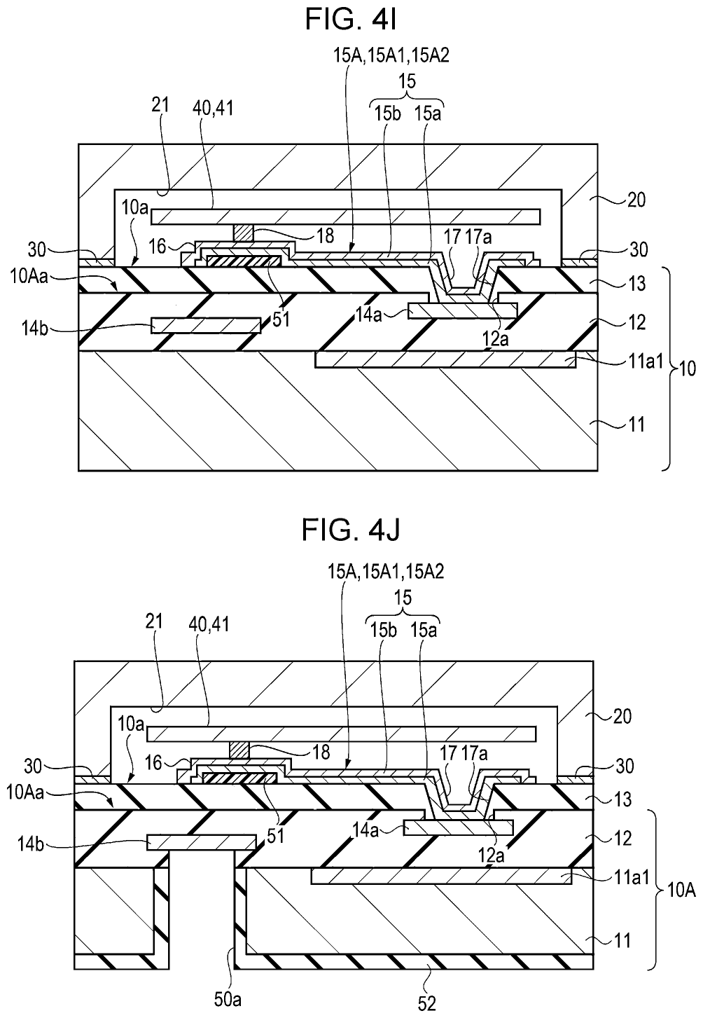

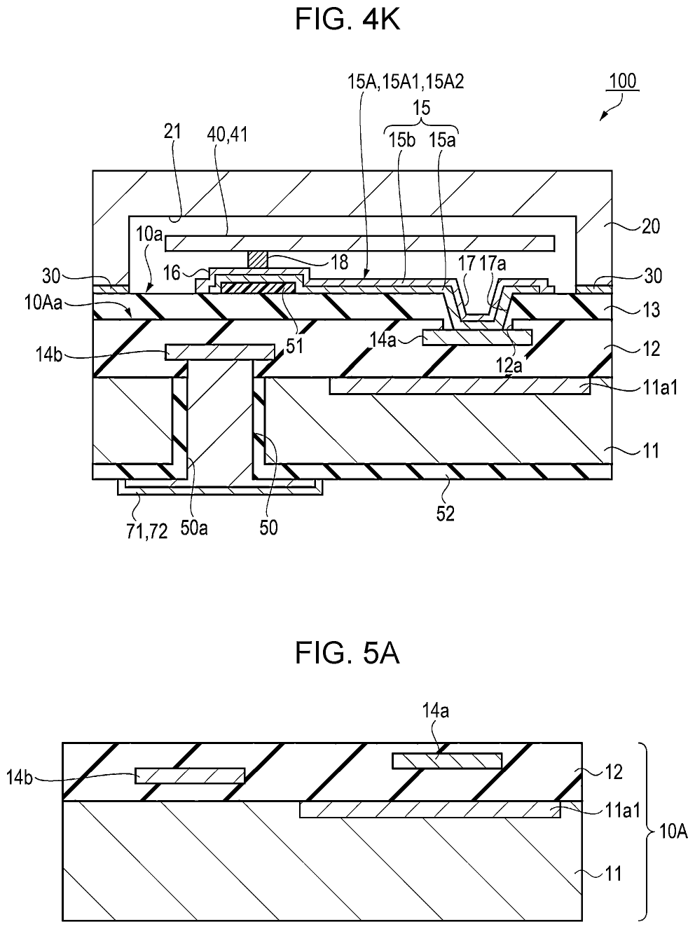

Next, a method for manufacturing the vibration device 100 will be described with reference to FIGS. 4A to 4K.

First, in a process illustrated in FIG. 4A, the base 10A is prepared. Specifically, first, the circuit element 11a1 including a transistor or the like is formed on the semiconductor substrate 11. Next, the first insulating layer 12 including the insulating layer, the wiring layers, the pad electrode 14a, and a pad electrode 14b is formed on the semiconductor substrate 11. The first insulating layer 12 is formed by using, for example, a chemical vapor deposition (CVD) method. Alternatively, the first insulating layer 12 may be formed by using a sputtering method. Then, an opening 12a is formed on the pad electrode 14a by photolithography and etching.

Next, in a process illustrated in FIG. 4B, the second insulating layer 13 is formed. Specifically, the second insulating layer 13 is formed on a surface of the first insulating layer 12 having the opening 12a on a side opposite to the semiconductor substrate 11, in other words, the fifth surface 10Aa of the base 10A, by depositing an oxide as an insulator by using, for example, the CVD method, similarly to the first insulating layer 12. Alternatively, the second insulating layer 13 may be formed by using a sputtering method. The surface of the second insulating layer 13, that is, the third surface 10a, is uneven because the wiring layers and the like are laminated below.

Since the second insulating layer 13 is formed by using, for example, the CVD method, gas used can easily penetrate and a strong and uniform film can be formed as the second insulating layer 13.

Next, in a process illustrated in FIG. 4C, the third surface 10a of the second insulating layer 13 is planarized. Specifically, the third surface 10a of the second insulating layer 13 on a side opposite to the base 10A is planarized by using, for example, a chemical mechanical polishing (CMP) method. As a result, the uneven third surface 10a of the second insulating layer 13 becomes even. Furthermore, since the planarizing is performed by using the CMP method, the third surface 10a of the second insulating layer 13 can be planarized relatively easily and accurately.

Next, in a process illustrated in FIG. 4D, the opening 17a is formed. Specifically, the opening 17a is formed by, for example, photolithography and etching in a region of the second insulating layer 13 which overlaps the pad electrode 14a in plan view. As a result, a part of the pad electrode 14a is exposed.

Next, in a process illustrated in FIG. 4E and FIG. 4F, the metal pattern 15A including the mount electrode 16 is formed. Specifically, as illustrated in FIG. 4E, a resin layer 51 is first formed on the second insulating layer 13 at a portion corresponding to the mount electrode 16. The resin layer 51 is selectively formed by using, for example, a coating method.

Next, the TiW film 15a is formed by using, for example, a sputtering method, on the second insulating layer 13 including the opening 17a and the resin layer 51. Then, a metal pattern 15A1 as the first layer is formed by photolithography and etching. As a result, a part of the mount electrode 16, a part of the wiring 15, and a part of the contact electrode 17 are formed.

Next, as illustrated in FIG. 4F, the Au film 15b is formed by using the CVD method or the like on the second insulating layer 13 on which the metal pattern 15A1 is formed. Then, a metal pattern 15A2 as the second layer is formed by photolithography and etching. In addition, the bonding layer 30 is formed. In this way, the metal pattern 15A is completed.

As described above, the mount electrode 16 is formed with the resin layer 51 interposed in between, so that when a stress is applied to the mount electrode 16, the stress can be alleviated, and when an impact is applied to the vibration device 100, the impact can be alleviated.

Next, in a process illustrated in FIG. 4G, the metal bump 18 is formed. Specifically, the metal bump 18 is formed on the mount electrode 16 by plating. The plating tends to reflect unevenness of an underlying base. However, since the underlying base, which is the second insulating layer 13, is planarized, the unevenness is less likely to appear on a surface of the metal bump 18.

Next, in a process illustrated in FIG. 4H, the vibration element 40 is bonded to the metal bump 18. Specifically, the first excitation electrode 42 (see FIG. 2) is formed on one side of the element substrate 41 made of a piezoelectric material such as quartz, and the second excitation electrode 43 (see FIG. 2) is formed on the other side of the element substrate 41. Thereafter, the completed vibration element 40 and the metal bump 18 are bonded to each other.

In the process illustrated in FIG. 4C, the third surface 10a of the second insulating layer 13 is planarized. Therefore, when the mount electrode 16 and the metal bump 18 are formed on the second insulating layer 13, a bonding area between the mount electrode 16 and the metal bump 18 is increased, so that the coupling can be made in an electrically stable state. As a result, the bonding area between the metal bump 18 and the vibration element 40 is increased, and the vibration element 40 and the circuit element 11a1 can be coupled in an electrically stable state.

Next, in a process illustrated in FIG. 4I, the base 10 and the lid 20 are bonded to each other. Specifically, first, the recess 21 is formed in a silicon substrate. Then, a TiW film and a Au film, a Ti film and a Au film, or the like are laminated by using, for example, a sputtering method, on the entire surface of the silicon substrate on a side where the recess 21 is provided. In this way, the lid 20 is completed.

Next, in a state in which the vibration element 40 is housed in the housing space between the base 10 and the lid 20, the bonding layer 30 formed on the polished third surface 10a of the second insulating layer 13 is bonded to the lid 20, for example, by using activated bonding. As a result, the vibration element 40 is hermetically sealed by the base 10 and the lid 20.

Next, in a process illustrated in FIG. 4J, a through hole 50a is formed in the base 10A. Specifically, first, the semiconductor substrate 11 is thinned. Then, the through hole 50a is formed in a region of the base 10A which overlaps the pad electrode 14b in plan view by photolithography and etching. Then, an insulating layer 52 made of silicon oxide is formed on the surface of the base 10A having the through hole 50a. Next, the insulating layer 52 is etched back to expose a surface of the pad electrode 14b.

Next, in a process illustrated in FIG. 4K, the vibration device 100 is completed. Specifically, first, for example, a W (tungsten) film is embedded in the through hole 50a, and a surface of the insulating layer 52 is patterned. Thereafter, a Au film is formed and patterned so as to cover the exposed W film, thereby completing the external coupling terminals 71 and 72. In this way, by forming the Au film on the exposed surfaces of the external coupling terminals 71 and 72, the external coupling terminals 71 and 72 can be protected from an external environment.

Next, the lid 20 is thinned. When the vibration device 100 is formed in a wafer, for example, the wafer is cut into individual pieces by using a cutting method such as dicing, thereby completing the vibration device 100.

As described above, the method for manufacturing the vibration device 100 of the present embodiment includes: preparing the base 10A including the semiconductor substrate 11 having the first surface 11a, on which the circuit element 11a1 is formed, and the second surface 11b, and the first insulating layer 12 disposed on the first surface 11a of the semiconductor substrate 11 and covering the circuit element 11a1; forming the second insulating layer 13 by depositing the insulator on the fifth surface 10Aa of the first insulating layer 12 on a side opposite to the semiconductor substrate 11; planarizing at least a part of the third surface 10a of the second insulating layer 13 on a side opposite to the base 10A by polishing; forming the mount electrode 16 on the polished third surface 10a of the second insulating layer 13; and bonding the vibration element 40 to the mount electrode 16.

According to the method, the third surface 10a of the second insulating layer 13 is planarized. Therefore, when the mount electrode 16 and the vibration element 40 are formed on the second insulating layer 13, the bonding area between the mount electrode 16 and the vibration element 40 is increased, so that the coupling can be made in an electrically stable state. As a result, the vibration element 40 and the circuit element 11a1 can be electrically coupled in a stable state.

In the method for manufacturing the vibration device 100 of the present embodiment, in the planarizing, the planarizing may be performed by using chemical mechanical polishing. According to the method, the planarizing is performed by using the chemical mechanical polishing, so that the third surface 10a of the second insulating layer 13 can be planarized relatively easily and accurately.

The method for manufacturing the vibration device 100 of the present embodiment may further include, after the bonding of the vibration element 40, bonding the lid 20 to the polished third surface 10a of the second insulating layer 13 in a state in which the vibration element 40 is housed in the housing space between the base 10 and the lid 20. According to the method, the lid 20 is bonded to the polished third surface 10a of the second insulating layer 13, specifically, to the bonding layer 30 formed on the third surface 10a, so that the base 10 and the lid 20 can be bonded to each other in a stable state, and hermetical sealing can be achieved.

In the method for manufacturing the vibration device 100 of the present embodiment, the forming of the second insulating layer 13 may be performed by using the CVD method. According to the method, the second insulating layer 13 is formed by using the CVD method, and thus, for example, gas used can easily penetrate and a strong and uniform film can be formed as the second insulating layer 13.

In the method for manufacturing the vibration device 100 of the present embodiment, the forming of the second insulating layer 13 may be performed by using the sputtering method. According to the method, the second insulating layer 13 is formed by using the sputtering method, and thus, for example, a manufacturing environment can be appropriately selected, which means the second insulating layer 13 can be manufactured under a wide range of environments.

In the method for manufacturing the vibration device 100 of the present embodiment, in the forming of the second insulating layer 13, an oxide may be deposited. According to the method, the second insulating layer 13 is formed by depositing an oxide, so that, for example, the wiring layers including the pad electrode 14a, the wiring, and the like can be electrically insulated from, for example, the mount electrode 16 coupled to the vibration element 40.

In the method for manufacturing the vibration device 100 of the present embodiment, in the bonding of the vibration element 40, the vibration element 40 may be bonded to the mount electrode 16 by using the metal bump 18. According to the method, since the vibration element 40 is bonded by using the metal bump 18, it is possible to inhibit the vibration element 40 from coming into contact with the wiring layers positioned below.

In the method for manufacturing the vibration device 100 of the present embodiment, in the forming of the mount electrode 16, the mount electrode 16 may be formed on the polished third surface 10a of the second insulating layer 13 with the resin layer 51 interposed in between. According to the method, the mount electrode 16 is formed with the resin layer 51 interposed in between, so that when a stress is applied to the mount electrode 16, the stress can be alleviated, and when an impact is applied to the vibration device 100, the impact can be alleviated.

Hereinafter, a modification of the above-described embodiment will be described.

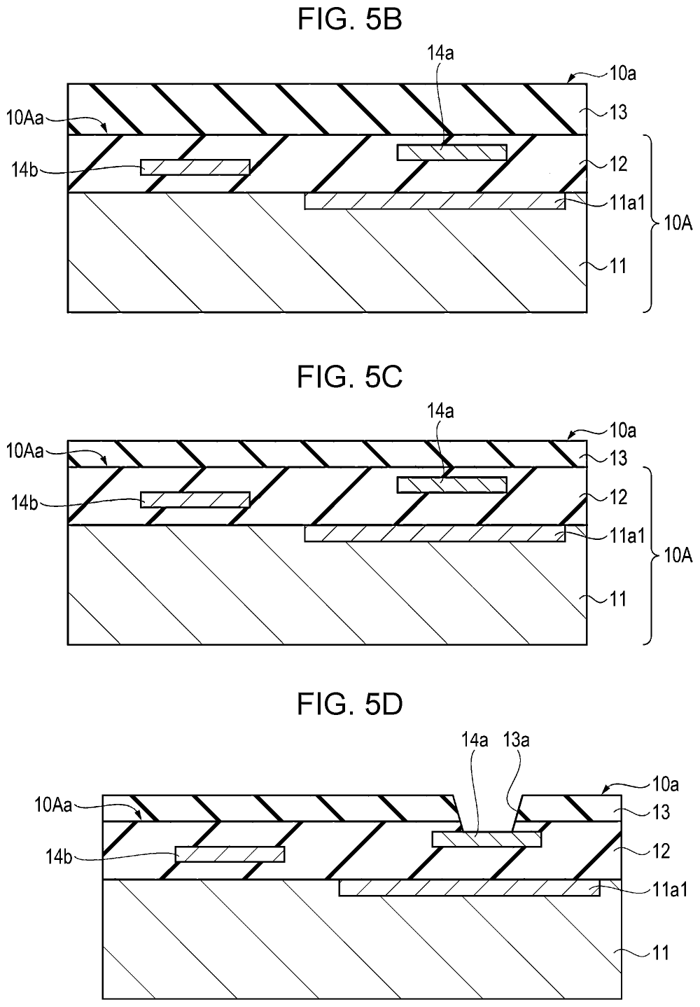

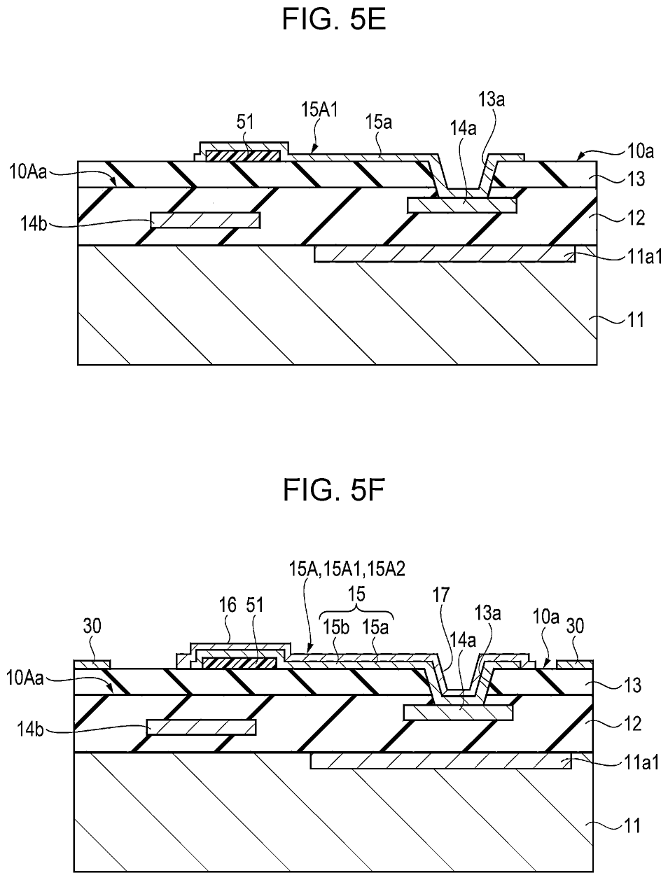

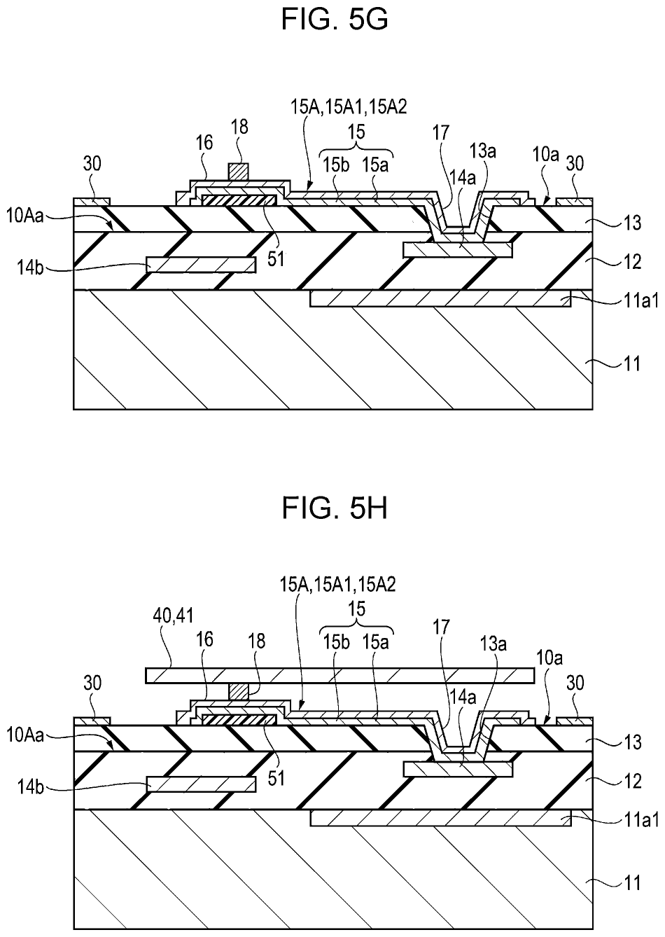

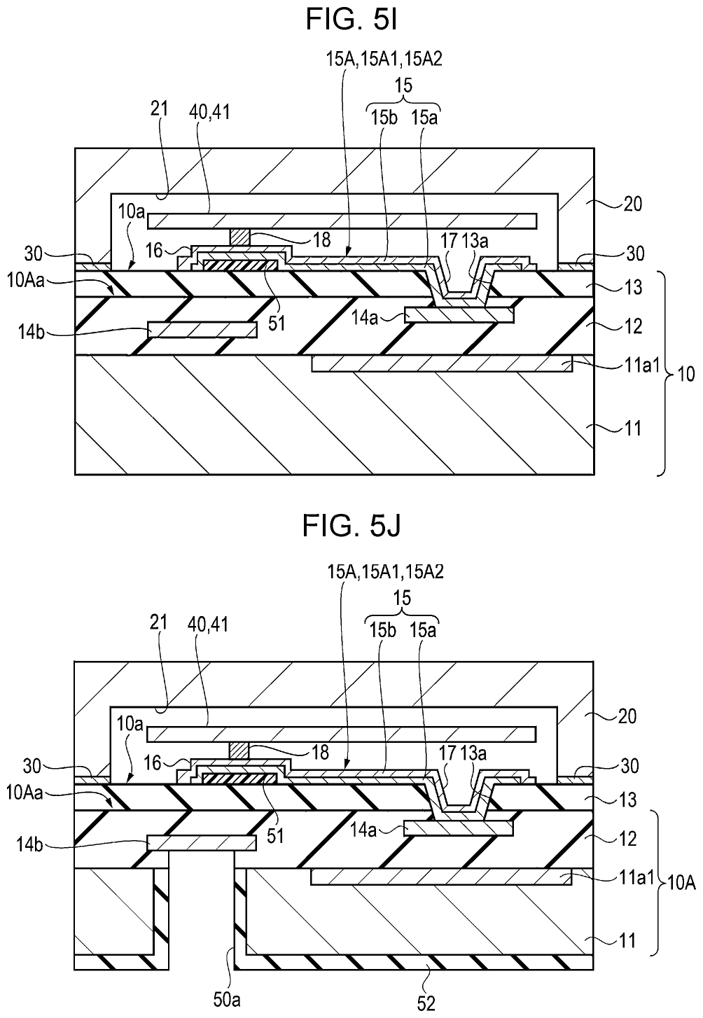

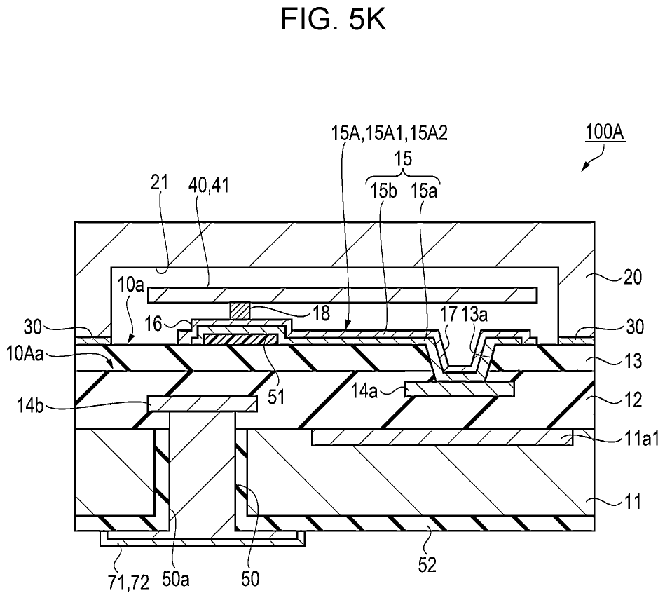

A method for forming the metal pattern 15A is not limited to the above-described manufacturing method illustrated in FIGS. 4A to 4K, and the metal pattern 15A may be formed by a manufacturing method illustrated in FIGS. 5A to 5K. A method for manufacturing a vibration device 100A according to the modification is different from the method in which the second insulating layer 13 is formed after the opening 12a is formed in the base 10A in that an opening 13a is formed after a second insulating layer 13 is formed on a base 10A. Hereinafter, only a difference from the above embodiment will be described.

Specifically, in a process illustrated in FIG. 5A, a first insulating layer 12 that covers pad electrodes 14a and 14b is formed on a semiconductor substrate 11 to complete the base 10A. In a process illustrated in FIG. 5B, the second insulating layer 13 is formed on the first insulating layer 12 of the base 10A. In a process illustrated in FIG. 5C, an uneven third surface 10a of the second insulating layer 13 is planarized by the CMP method. In a process illustrated in FIG. 5D, etching is performed on a region of the first insulating layer 12 and the second insulating layer 13 which overlaps the pad electrode 14a in plan view to form the opening 13a. As a result, a surface of the pad electrode 14a is exposed.

Then, similarly to the above embodiment, the vibration device 100A according to the modification in which the opening 13a is formed in a shape illustrated in FIG. 5D is completed by the processes in FIGS. 5E to 5K. Also in this case, a mount electrode 16 is bonded onto the planarized second insulating layer 13, so that a vibration element 40 and a metal bump 18 and also the vibration element 40 and a circuit element 11a1 can be electrically coupled in a stable state.

As described above, in the method for manufacturing the vibration device 100A according to the modification, the base 10A includes the pad electrodes 14a and 14b covered with the first insulating layer 12 and electrically coupled to the circuit element 11a1, and the forming of the mount electrode 16 includes forming the opening 13a in a region, of the first insulating layer 12 and the second insulating layer 13, which overlaps the pad electrode 14a in plan view to expose a part of the pad electrode 14a, and forming a metal pattern 15A including the mount electrode 16 and wiring 15 that couples the exposed pad electrode 14a and the mount electrode 16 to each other. According to the method, the metal pattern 15A electrically coupled to the circuit element 11a1 is coupled to the mount electrode 16, so that the circuit element 11al and the vibration element 40 can be coupled in an electrically stable state.

The planarizing is not limited to planarizing of the entire third surface 10a of the second insulating layer 13 as described above, and at least a portion of the third surface 10a of the second insulating layer 13 on a side opposite to the base 10A, specifically, only a portion where the mount electrode 16 is formed and a portion where the bonding layer 30 is formed may be planarized by polishing.

A method for bonding the base 10 and the lid 20 is not limited to bonding the lid 20 on the second insulating layer 13 with the bonding layer 30 interposed in between as described above, and, for example, the bonding may be performed by performing etching up to a surface of the semiconductor substrate 11 of the base 10A in a bonding region to expose the planar surface.

The formation of the bonding layer 30 is not limited to forming the bonding layer 30 by using the Au film 15b as described above. For example, the TiW film 15a, which is the metal pattern 15A1 as the first layer, may be formed and then the metal film may be planarized. Thereafter, the metal pattern 15A is formed.

In the above description, the resin layer 51 is formed under the mount electrode 16, but the present disclosure is not limited thereto. The mount electrode 16 may be formed without forming the resin layer 51.

What is claimed is:

1. A method for manufacturing a vibration device, the method comprising:
preparing a base including a semiconductor substrate having a first surface, on which a circuit element is formed, and a second surface, and a first insulating layer disposed on the first surface of the semiconductor substrate and covering the circuit element;
forming a second insulating layer by depositing an insulator on a surface of the first insulating layer on a side opposite to the semiconductor substrate;
planarizing at least a part of a surface of the second insulating layer on a side opposite to the base by polishing;
forming a mount electrode on the polished surface of the second insulating layer; and
bonding a vibration element to the mount electrode.

2. The method for manufacturing a vibration device according to claim 1, wherein in the planarizing, the planarizing is performed by using chemical mechanical polishing.

3. The method for manufacturing a vibration device according to claim 1, further comprising, after the bonding of the vibration element, bonding a lid to the polished surface of the second insulating layer in a state in which the vibration element is housed in a housing space between the base and the lid.

4. The method for manufacturing a vibration device according to claim 1, wherein the forming of the second insulating layer is performed by using a chemical vapor deposition (CVD) method.

5. The method for manufacturing a vibration device according to claim 1, wherein the forming of the second insulating layer is performed by using a sputtering method.

6. The method for manufacturing a vibration device according to claim 1, wherein in the preparing of the base, the base includes a pad electrode covered with the first insulating layer and electrically coupled to the circuit element, and
the forming of the mount electrode includes
forming an opening in a region, of the first insulating layer and the second insulating layer, which overlaps the pad electrode in plan view to expose a part of the pad electrode, and
forming a metal pattern including the mount electrode and wiring that couples the exposed pad electrode and the mount electrode to each other.

7. The method for manufacturing a vibration device according to claim 1, wherein in the forming of the second insulating layer, an oxide is deposited.

8. The method for manufacturing a vibration device according to claim 1, wherein in the bonding of the vibration element, the vibration element is bonded to the mount electrode by using a metal bump.

9. The method for manufacturing a vibration device according to claim 1, wherein in the forming of the mount electrode, the mount electrode is formed on the polished surface of the second insulating layer with a resin layer interposed in between.
